(19) United States
(12) Patent Application Publication
(10) Pub. No.: US 2026/0052818 A1
(43) Pub. Date: Feb. 19, 2026

(54) DISPLAY DEVICE AND ELECTRONIC DEVICE INCLUDING THE SAME

(71) Applicant: Samsung Display Co., LTD., Yongin-si (KR)

(72) Inventors: Jung Hyun KWON, Yongin-si (KR); Young Min KIM, Yongin-si (KR); Hyun Woo NOH, Yongin-si (KR); Moon Jung BAEK, Yongin-si (KR)

(21) Appl. No.: 19/289,580

(22) Filed: Aug. 4, 2025

(30) Foreign Application Priority Data
Aug. 19, 2024 (KR) 10-2024-0110213

(51) Int. Cl. H10H 29/37; H10H 29/80

(52) U.S. Cl. CPC H10H 29/37; H10H 29/882

(57) ABSTRACT

A display device includes a pixel defining layer surrounding an emission area, a first electrode including a first electrode layer and a second electrode layer, a scattering layer disposed between the first electrode layer and the second electrode layer, a light emitting layer disposed on the pixel defining layer and the first electrode, and a second electrode disposed on the light emitting layer. A width of the scattering layer is smaller than a width of the emission area.

This application claims priority to Korean Patent Application No. 10-2024-0110213, filed on Aug. 19, 2024, and all the benefits accruing therefrom under 35 U.S.C. § 119, the content of which in its entirety is herein incorporated by reference.

### BACKGROUND

### 1. Technical Field

The invention generally relates to a display device, and more particularly to a display device and an electronic device including the same.

### 2. Related Art

Recently, as interest in information displays has increased, research and development of display devices have been continuously conducted.

### SUMMARY

An embodiment includes a display device in which viewing angle characteristics of the display device can be improved and front emission efficiency can be enhanced.

In accordance with an embodiment, there is provided a display device including a pixel defining layer surrounding an emission area, a first electrode including a first electrode layer and a second electrode layer, a scattering layer disposed between the first electrode layer and the second electrode layer, a light emitting layer disposed on the pixel defining layer and the first electrode and a second electrode disposed on the light emitting layer, wherein a width of the scattering layer is smaller than a width of the emission area.

In an embodiment, the second electrode layer may be disposed between the first electrode layer and the light emitting layer.

In an embodiment, the emission area may include a first area overlapping with the scattering layer and a second area not overlapping with the scattering layer, wherein the second area overlaps with the second electrode layer.

In an embodiment, the second area may surround the first area on a plane.

In an embodiment, an area of the first area may be greater than an area of the second area.

In an embodiment, the emission area may further include a third area not overlapping with the second electrode layer, wherein the third area overlaps with the first electrode layer.

In an embodiment, the third area may surround the second area on a plane.

In an embodiment, an area of the third area may be greater than the area of the first area.

In an embodiment, an area of the third area may be greater than the area of the second area.

In an embodiment, a width of the second electrode layer may be greater than the width of the scattering layer and smaller than the width of the emission area.

In an embodiment, the width of the emission area may be greater than a width of the second electrode layer and smaller than a width of the first electrode layer.

In an embodiment, the pixel defining layer may include a scatterer.

In an embodiment, the pixel defining layer may include at least one penetration hole.

In accordance with another embodiment, there is provided a display device including a pixel defining layer including an opening exposing a first electrode layer, a scattering layer disposed in the same layer as the pixel defining layer, the scattering layer being spaced apart from the pixel defining layer on a plane, a second electrode layer on the scattering layer, a light emitting layer disposed on the second electrode layer and a second electrode disposed on the light emitting layer.

In an embodiment, the pixel defining layer and the scattering layer may be disposed directly on the first electrode layer.

In an embodiment, the pixel defining layer and the scattering layer may include the same material.

In an embodiment, the pixel defining layer may include a scatterer.

In an embodiment, the pixel defining layer may surround the scattering layer on a plane.

In an embodiment, on a plane, the pixel defining layer may be spaced apart from the second electrode and may surround the second electrode.

In an embodiment, a width of the second electrode layer may be greater than a width of the scattering layer and smaller than a width of the opening.

In accordance with another embodiment, there is provided an electronic device including a processor to provide input image data, and a display device to display an image based on the input image data, the display device including sub-pixel areas, wherein the display device comprises a pixel defining layer surrounding an emission area, a first electrode including a first electrode layer and a second electrode layer, a scattering layer disposed between the first electrode layer and the second electrode layer, a light emitting layer disposed on the pixel defining layer and the first electrode and a second electrode disposed on the light emitting layer, wherein a width of the scattering layer is smaller than a width of the emission area.

### BRIEF DESCRIPTION OF THE DRAWINGS

Example embodiments will now be described more fully hereinafter with reference to the accompanying drawings. The invention should not be construed as limited to the embodiments set forth herein. Rather, these embodiments are provided so that this disclosure will be thorough and complete, and will fully convey the scope of the invention to those skilled in the art.

In the drawing figures, dimensions may be exaggerated for clarity of illustration. It will be understood that when an element is referred to as being disposed “between” two elements, it can be the only element between the two elements, or one or more intervening elements may also be present. Like reference numerals refer to like elements throughout.

FIG. 1 is a plan view illustrating a display panel, in accordance with an embodiment.

FIG. 2 is a plan view illustrating a pixel, in accordance with an embodiment.

FIG. 3 is a cross-sectional view taken along line A-A′ shown in FIG. 2, according to an embodiment.

FIG. 4 is a plan view of an emission area, in accordance with an embodiment.

FIG. 5 is a plan view of an emission area, in accordance with an embodiment.

FIG. 6 is a plan view of an emission area, in accordance with an embodiment.

FIG. 7 is a sectional view taken along line B-B′ shown in FIG. 4, according to an embodiment.

FIG. 8 is a sectional view taken along line B-B′ shown in FIG. 4, according to an embodiment.

FIG. 9 is a sectional view illustrating process steps of a method of manufacturing a display device, in accordance with an embodiment.

FIG. 10 is a sectional view illustrating process steps of a method of manufacturing a display device, in accordance with an embodiment.

FIG. 11 is a sectional view illustrating process steps of a method of manufacturing a display device, in accordance with an embodiment.

FIG. 12 is a sectional view illustrating process steps of a method of manufacturing a display device, in accordance with an embodiment.

FIG. 13 is a sectional view illustrating process steps of a method of manufacturing a display device, in accordance with an embodiment.

FIG. 14 is a sectional view illustrating process steps of a method of manufacturing a display device, in accordance with an embodiment.

FIG. 15 is a sectional view illustrating process steps of a method of manufacturing a display device, in accordance with an embodiment.

FIG. 16 is a sectional view illustrating process steps of a method of manufacturing a display device, in accordance with an embodiment.

FIG. 17 is a block diagram illustrating an electronic device including a display device, in accordance with an embodiment.

FIG. 18 is a graphical image illustrating an embodiment where the electronic device of FIG. 17 is a smartphone.

FIG. 19 is a graphical image illustrating an embodiment where the electronic device of FIG. 17 is a tablet computer.

### DETAILED DESCRIPTION

Hereinafter, embodiments of the invention are described in more detail with reference to the accompanying drawings. In the description below, only a necessary part to understand an operation according to the invention is described and the descriptions of other parts are omitted in order not to unnecessarily obscure subject matters of the invention. In addition, the invention is not limited to exemplary embodiments described herein, but may be embodied in various different forms. Rather, exemplary embodiments described herein are provided to thoroughly and completely describe the invention and to sufficiently transfer the ideas of the invention to a person of ordinary skill in the art.

In the specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the invention.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, embodiments are described here with reference to schematic diagrams of ideal embodiments (and an intermediate structure), so that changes in a shape as shown due to, for example, manufacturing technology and/or a tolerance may be expected. Therefore, the invention shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the invention.

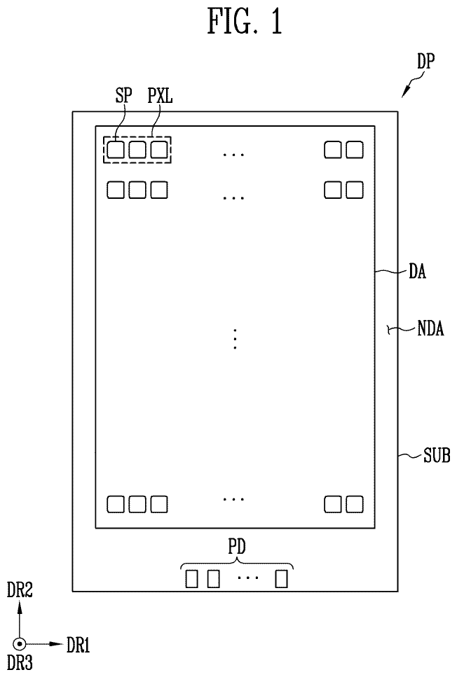

FIG. 1 is a plan view illustrating a display panel, in accordance with an embodiment.

In an embodiment and referring to FIG. 1, the display panel (or display device) DP may include a display area DA and a non-display area NDA, where the display panel DP may display an image through the display area DA. The non-display area NDA may be disposed at the periphery of the display area DA.

In an embodiment, the display panel DP may include a substrate SUB, sub-pixels SP, and/or pads PD.

In an embodiment, the sub-pixels SP may be disposed in the display area DA on the substrate SUB and may be arranged in a matrix form along a first direction DR1 and a second direction DR2 intersecting the first direction DR1. However, the invention is not limited thereto. For example, the sub-pixels SP may be arranged in a zigzag form along the first direction DR1 and the second direction DR2. For example, the sub-pixels SP may be disposed in a PENTILE™ form. The first direction DR1 may be a row direction, and the second direction DR2 may be a column direction. Two or more sub-pixels among the sub-pixels SP may constitute one pixel PXL.

In an embodiment, a component for controlling the sub-pixels SP may be disposed in the non-display area NDA on the substrate SUB. For example, lines connected to the sub-pixels SP, such as gate lines and data lines may be disposed in the non-display area NDA.

In an embodiment, the pads PD may be disposed in the non-display area NDA on the substrate SUB and may be electrically connected to the sub-pixels SP through the lines. For example, the pads PD may be connected to the sub-pixels SP through the data lines.

In an embodiment, voltages and signals, which are necessary for operations of components included in the display panel DP, may be provided from a driver integrated circuit through the pads PD. For example, the data lines may be connected to the driver integrated circuit through the pads PD. For example, power voltages may be received from the driver integrated circuit through the pads PD.

In an embodiment, a circuit board may be electrically connected to the pads PD, using a conductive adhesive member such as an anisotropic conductive film. The circuit board may be a flexible circuit board or a flexible film, which has a flexible material. The driver integrated circuit may be mounted on the circuit board to be electrically connected to the pads PD.

In an embodiment, the display area DA may have various shapes. The display area DA may have a closed-loop shape including linear sides and/or curved sides. For example, the display area DA may have shapes such as a polygon, a circle, a semicircle, and an ellipse.

In an embodiment, the display panel DP may have a flat display surface. In another embodiment, the display panel DP may at least partially have a round display surface. In another embodiment, the display panel DP may be bendable, foldable or rollable, where the display panel DP and/or the substrate SUB may include materials having flexibility.

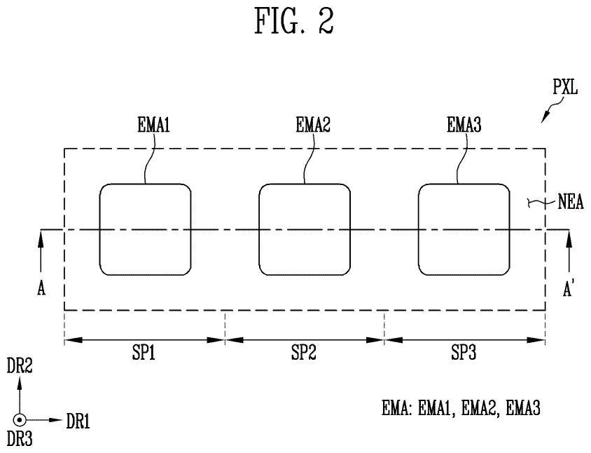

FIG. 2 is a plan view illustrating a pixel, in accordance with an embodiment.

In an embodiment and referring to FIG. 2, the display panel DP may include first to third sub-pixels SP1 to SP3, respectively, arranged in the first direction DR1.

In an embodiment, the first sub-pixel SP1 may include a first emission area EMA1 and a non-emission area NEA disposed at the periphery of the first emission area EMA1. The second sub-pixel SP2 may include a second emission area EMA2 and the non-emission area NEA disposed at the periphery of the second emission area EMA2. The third sub-pixel SP3 may include a third emission area EMA3 and the non-emission area NEA disposed at the periphery of the third emission area EMA3.

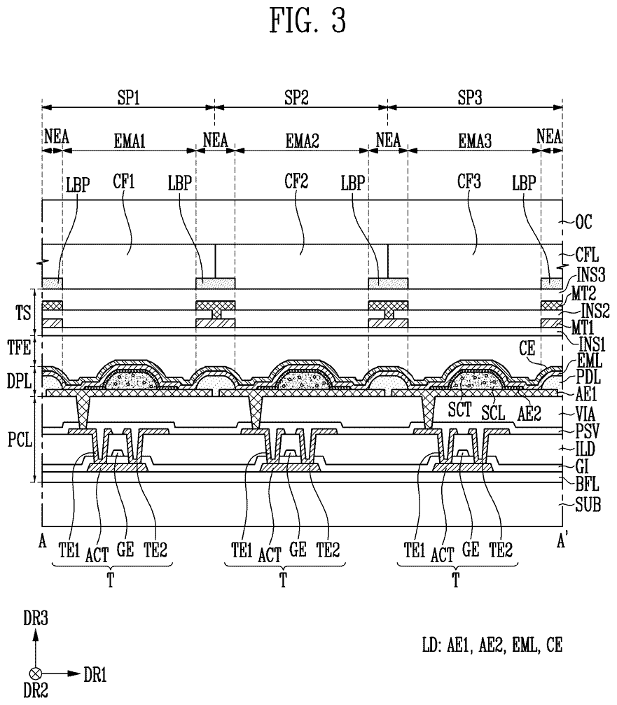

In an embodiment, the first emission area EMA1 may be an area in which light is emitted from a light emitting layer EML (see FIG. 3) of the first sub-pixel SP1. The second emission area EMA2 may be an area in which light is emitted from the light emitting layer EML of the second sub-pixel SP2. The third emission area EMA3 may be an area in which light is emitted from the light emitting layer EML of the third sub-pixel SP3.

FIG. 3 is a sectional view taken along line A-A′ shown in FIG. 2, according to an embodiment.

In an embodiment and referring to FIG. 3, each of the sub-pixels SP1 to SP3 may include emission area EMA, and the non-emission area NEA may be located between the emission areas EMA of the sub-pixels SP1 to SP3.

In an embodiment, each of the sub-pixels SP1 to SP3 may include a pixel circuit layer PCL, a display element layer DPL, and/or a thin film encapsulation layer TFE, which are sequentially disposed on a substrate SUB.

In an embodiment, the substrate SUB may form a base surface, where the substrate SUB may be a rigid substrate or a flexible substrate. The substrate SUB may include a transparent insulating material to allow light to be transmitted therethrough, but the invention is not necessarily limited thereto.

In an embodiment, the pixel circuit layer PCL may include a pixel circuit provided on the substrate SUB, where the pixel circuit layer PCL may include a buffer layer BFL, a gate insulating layer GI, an interlayer insulating layer ILD, a passivation layer PSV, and/or a via layer VIA, which are sequentially stacked on the substrate SUB along a third direction DR3.

In an embodiment, the buffer layer BFL may be an inorganic insulating layer including an inorganic material. The buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer, but in another embodiment may be provided as a multi-layer including at least two layers. When the buffer layer BFL is provided as the multi-layer, the layers may be formed of the same material or be formed of different materials. The buffer layer BFL may be omitted according to a material of the substrate SUB, a process condition, and the like.

In an embodiment, t transistor T may be disposed on the buffer layer BFL and may include an active pattern ACT, a gate electrode GE, a first transistor electrode TE1, and/or a second transistor electrode TE2.

In an embodiment, the active pattern ACT may be disposed on the buffer layer BFL. The active pattern ACT may include a poly-silicon semiconductor. For example, the active pattern ACT may be formed through a low temperature poly-silicon process. However, the invention is not necessarily limited thereto, and the active pattern ACT may be formed of an oxide semiconductor, a metal oxide semiconductor, or the like.

In an embodiment, the active pattern ACT may include a channel region, a first contact region connected to one end of the channel region, and a second contact region connected to the other end of the channel region. The channel region, the first contact region, and the second contact region may be formed with a semiconductor layer undoped or doped with an impurity. In an example, the first contact region and the second contact region may be formed with a semiconductor layer doped with the impurity, and the channel region may be formed with a semiconductor layer undoped with the impurity. A p-type impurity may be used as an example of the impurity, but the present disclosure is not limited thereto. One of the first and second contact regions may be a source region, and the other of the first and second contact regions may be a drain region.

In an embodiment, the gate insulating layer GI may be disposed over the active pattern ACT, where the gate insulating layer GI may be an inorganic layer (or inorganic insulating layer) including an inorganic material. In an example, the gate insulating layer GI may include at least one of silicon nitride (SiNₓ), silicon oxide (SiOₓ), silicon oxynitride (SiOₓN_{y}), and a metal oxide such as aluminum oxide (AlOₓ). However, the material of the gate insulating layer GI is not limited to the above-described embodiments. In some embodiments, the gate insulating layer GI may be an organic layer (or organic insulating layer) including an organic material. The gate insulating layer GI may be provided as a single layer, but may also be provided as a multi-layer including at least two layers.

In an embodiment, the gate electrode GE may be disposed on the gate insulating layer GI. The gate electrode GE may overlap with a channel region of the active pattern ACT. The gate electrode GE may form a single layer, using one selected from the group consisting of copper (Cu), molybdenum (Mo), tungsten (W), aluminum neodymium (AlNd), titanium (Ti), aluminum (Al), and silver (Ag), or a mixture thereof, or be formed in a double-layer or multi-layer structure including molybdenum (Mo), titanium (Ti), copper (Cu), aluminum (Al), and silver (Ag), which are low resistance materials, to reduce wiring resistance.

In an embodiment, the interlayer insulating layer ILD may be disposed over the gate electrode GE, where the interlayer insulating layer ILD may include the same material as the gate insulating layer GI, or include at least one material from the materials exemplified as the material constituting the gate insulating layer GI.

In an embodiment, the first transistor electrode TE1 and the second transistor electrode TE2 may be disposed on the interlayer insulating layer ILD. The first transistor electrode TE1 of the transistor T may be in contact with the first contact region of the active pattern ACT through a contact hole penetrating the interlayer insulating layer ILD and the gate insulating layer GI. When the first contact region is the source region, the first transistor electrode TE1 may be a first source electrode.

In an embodiment, the second transistor electrode TE2 of the transistor T may be in contact with the second contact region of the other end of the active pattern ACT through a contact hole penetrating the interlayer insulating layer ILD and the gate insulating layer GI. When the second contact region is the drain region, the second transistor electrode TE2 may be a second drain electrode.

In an embodiment, each of the first transistor electrode TE1 and the second transistor electrode TE2 may include the same material as the gate electrode GE, or include at least one material from the materials exemplified as the material constituting the gate electrode GE.

In an embodiment, the passivation layer PSV may be disposed over the first transistor electrode TE1 and the second transistor electrode TE2. The passivation layer PSV (e.g., a protective layer) may be an inorganic layer (or inorganic insulating layer) including an inorganic material or an organic layer (or organic insulating layer) including an organic material. The inorganic layer may include, for example, at least one of silicon nitride (SiNₓ), silicon oxide (SiOₓ), silicon oxynitride (SiOₓN_{y}), and a metal oxide such as aluminum oxide (AlOₓ). The organic layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

In an embodiment, the passivation layer PSV may include the same material as the interlayer insulating layer ILD, but the invention is not limited thereto. The passivation layer PSV may be provided as a single layer, but also may be provided as a multi-layer including at least two layers.

In an embodiment, the via layer VIA may be disposed on the passivation layer PSV and may include the same material as the passivation layer PSV, or include at least one material from the materials exemplified as the material constituting the passivation layer PSV. In an embodiment, the via layer VIA may be an organic layer including an organic material.

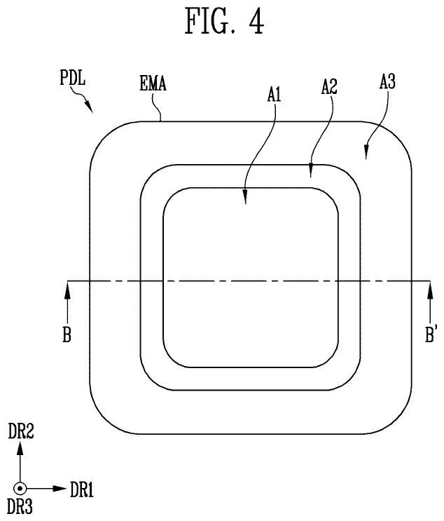

In an embodiment, the display element layer DPL may be disposed on the pixel circuit layer PCL. The display element layer DPL may include an anode electrode (or first electrode) AE, a pixel defining layer PDL, a scattering layer SCL, a light emitting layer EML, and/or a cathode electrode (or second electrode) CE. This will be described in detail with reference to FIGS. 4 to 8.

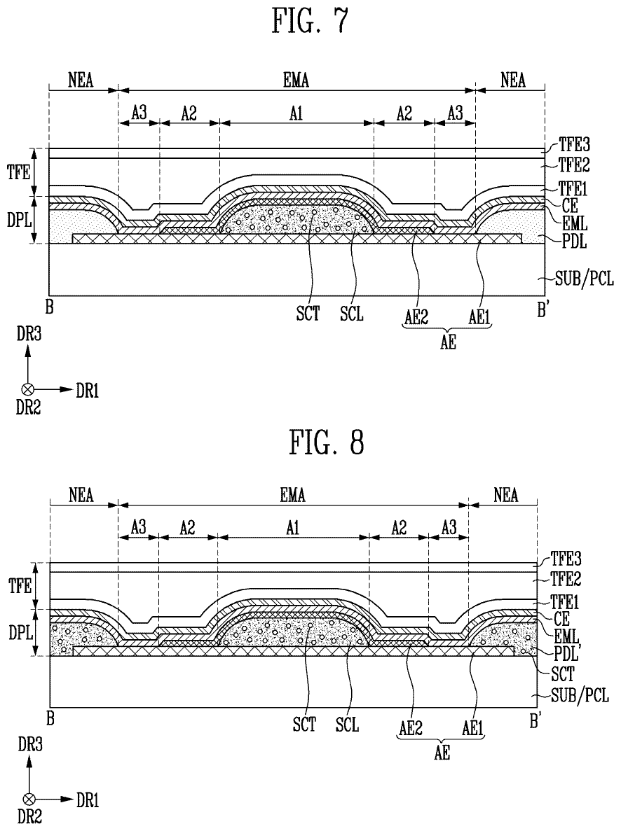

FIGS. 4 to 6 are plan views of an emission area, in accordance with an embodiment. FIGS. 7 and 8 are sectional views taken along line B-B′ shown in FIG. 4, according to an embodiment.

In an embodiment and referring to FIGS. 3 to 8, the anode electrode AE may include a first electrode layer AE1 and a second electrode layer AE2. The first electrode layer AE1 may be disposed on the via layer VIA and may be electrically connected to a first transistor electrode TE1 of a transistor T of each sub-pixel SP through a contact hole penetrating the via layer VIA and the passivation layer PSV. A width of the first electrode AE1 in the first direction DR1 may be greater than a width of the emission area EMA in the first direction DR1.

In an embodiment, the first electrode layer AE1 may function to reflect light emitted from the light emitting layer EML toward a display surface, a display direction, or a front direction (e.g., the third direction DR3), thereby improving light emission efficiency. The first electrode layer AE1 may include metal materials suitable for reflecting light. The first electrode layer AE1 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but the invention is not limited thereto. For example, the first electrode layer AE1 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). In an example, the first electrode layer AE1 may be formed in a structure in which indium tin oxide (ITO), silver (Ag), and indium tin oxide (ITO) are sequentially stacked, but the invention is not necessarily limited thereto.

In an embodiment, the second electrode layer AE2 may be disposed on the first electrode layer AE1. The second electrode layer AE2 may be disposed directly on the first electrode layer AE1 and may be disposed at a center of the emission area EMA. A width of the second electrode layer AE2 in the first direction DR1 may be smaller than the width of the emission area EMA in the first direction DR1. The width of the second electrode layer AE2 in the first direction DR1 may be smaller than the width of the first electrode layer AE1 in the first direction DR1. In an example, the second electrode layer AE2 may partially expose the first electrode layer AE1.

In an embodiment, the second electrode layer AE2 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO), but the invention is not necessarily limited thereto.

In an embodiment, the scattering layer SCL may be disposed between the first electrode layer AE1 and the second electrode layer AE2, where the scattering layer SCL may be disposed directly on the first electrode layer AE1. The second electrode layer AE2 may be disposed directly over the scattering layer SCL. The second electrode layer AE2 may entirely cover the scattering layer SCL.

In an embodiment, the scattering layer SCL may scatter light reflected by the first electrode layer AE1, thereby improving viewing angle characteristics of the display device, e.g., White Angular Dependency (WAD) of the display device. The scattering layer SCL may include a plurality of scatterers dispersed in a matrix material such as a base resin. In an embodiment, the scattering layer SCL may include a scatterer SCT such as silica, where the scatterer SCT may have a diameter of about 150 nm to about 500 nm, but the invention is not necessarily limited thereto.

In an embodiment, the scattering layer SCL may be disposed at a center of the emission area EMA, where a width of the scattering layer SCL in the first direction DR1 may be smaller than the width of the emission area EMA in the first direction DR1. The width of the scattering layer SCL in the first direction DR1 may be smaller than the width of the first electrode layer AE1 in the first direction DR1. The width of the scattering layer SCL in the first direction DR1 may be smaller than the width of the second electrode layer AE2 in the first direction DR1.

In an embodiment, the pixel defining layer PDL may be disposed on the first electrode layer AE1, where the pixel defining layer PDL may be disposed directly on the first electrode layer AE1. In an embodiment, the pixel defining layer PDL may be disposed in the same layer as the scattering layer SCL. The pixel defining layer PDL may be spaced apart from the scattering layer SCL on a plane. The pixel defining layer PDL may surround the scattering layer SCL on a plane. On a plane, the pixel defining layer PDL may be spaced apart from the second electrode layer AE2 and may surround the second electrode layer AE2.

In an embodiment, the pixel defining layer PDL may be an organic insulating layer made of an organic material, where the organic material may include acrylic resin, epoxy resin, phenolic resin, polyamide resin, polyimide resin, and the like.

In some embodiments, the pixel defining layer PDL may include a light absorption material or have a light absorber coated thereon, to absorb light introduced from the outside. For example, the pixel defining layer PDL may include a carbon-based black pigment. However, the invention is not necessarily limited thereto, and the pixel defining layer PDL may include an opaque metal material, such as chromium (Cr), molybdenum (Mo), any alloy (MoTi) of molybdenum and titanium, tungsten (W), vanadium (V), niobium (Nb), tantalum (Ta), manganese (Mn), cobalt (Co) or nickel (Ni), which has a high absorption rate.

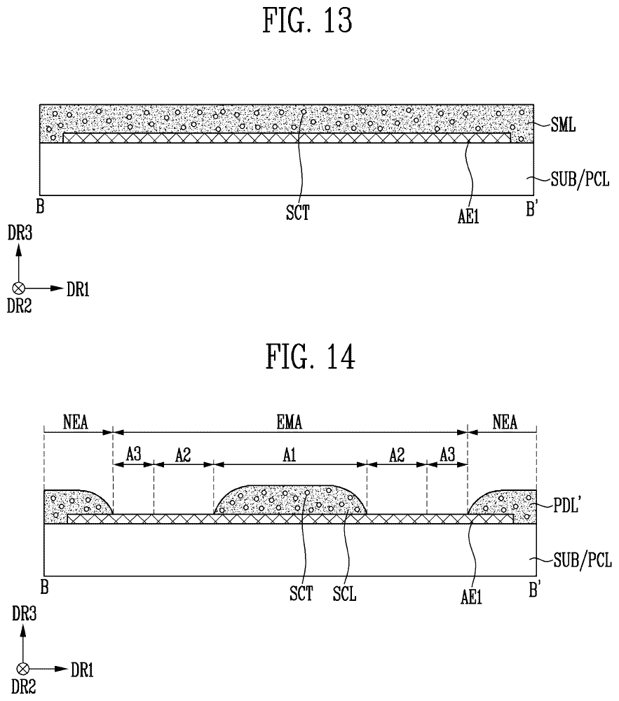

In some embodiments, a pixel defining layer PDL′ may include a scatterer SCT as shown in FIG. 8, where the pixel defining layer PDL′ may include a scatterer SCT such as silica. The pixel defining layer PDL′ may include the same material as the scattering layer SCL. The pixel defining layer PDL′ may include the same scatterer SCT as the scattering layer SCL. In an embodiment, the pixel defining layer PDL′ and the scattering layer SCL may be simultaneously formed through the same process. Accordingly, the number of masks is decreased, thereby simplifying processes and reducing cost. This will be described in detail with reference to FIGS. 13 and 14.

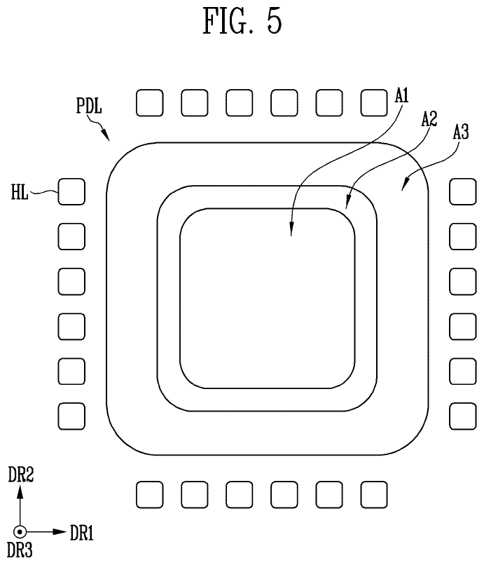

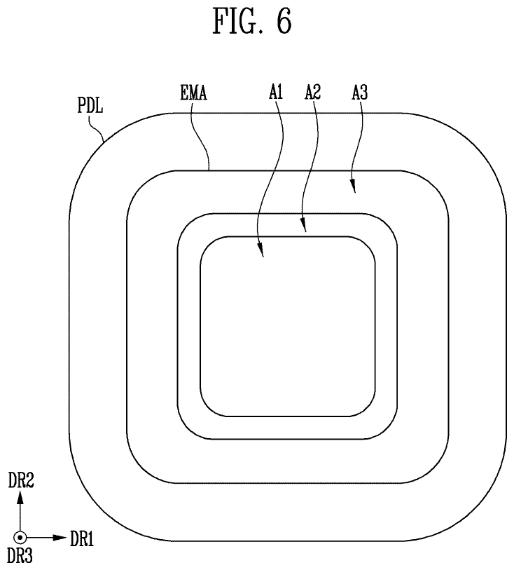

In an embodiment, the pixel defining layer PDL may surround the emission area EMA. For example, as shown in FIG. 4, the pixel defining layer PDL may be entirely formed on the substrate SUB on a plane to surround the emission area EMA. In some embodiments, when the pixel defining layer PDL is entirely formed on the substrate SUB, the pixel defining layer PDL may include at least one penetration hole HL as shown in FIG. 5. In another embodiment, the pixel defining layer PDL may be partially formed at the periphery of the emission area EMA on a plane as shown in FIG. 6.

In an embodiment, the pixel defining layer PDL may define (or partition) an emission area EMA of each sub-pixel SP. In an example, the pixel defining layer PDL may include an opening partially exposing the first electrode layer AE1, where a width of the opening of the pixel defining layer PDL in the first direction may be smaller than the width of the first electrode layer AE1 in the first direction DR1.

In an embodiment, the emission area EMA may include a first area A1, a second area A2, and/or a third area A3. The first area A1 may be a scattering area and may be an area in which the scattering layer SCL is disposed. The first area A1 may overlap with the scattering layer SCL. In an example, light reflected by the first electrode layer AE1 may be scattered by the scattering layer SCL in the first area A1. Accordingly, the viewing angle characteristics of the display device can be improved, which has been described above.

In an embodiment, the second area A2 and/or the third area A3 except the first area A1 in which the scattering layer SCL is disposed may be a resonance area(s). The second area A2 and/or the third area A3 may be an area(s) in which the scattering layer SCL is not disposed. The second area A2 and/or the third area A3 may not overlap with the scattering layer SCL. In an example, light emitted from the light emitting layer EML may be amplified by reciprocating between the first electrode AE1 and the cathode electrode CE in the second area A2 and/or the third area AE3, and the amplified light may be emitted through the cathode electrode CE. Accordingly, although the scattering layer SCL is formed in the emission area EMA, front emission efficiency can be improved by resonance of the second area A2 and the third area A3.

In an embodiment, the second area A2 may be a weak resonance area, and the third area A3 may be a strong resonance area. A distance between the first electrode layer AE1 and the cathode electrode CE may be understood as a resonance distance of light emitted from the light emitting layer EML. In an embodiment, a distance between the first electrode layer AE1 and the cathode electrode CE in the second area A2 and a distance between the first electrode layer AE1 and the cathode electrode CE in the third area A3 may be formed different from each other, and therefore, a relatively strong resonance may occur in the third area A3. Light generated in the light emitting layer EML may be emitted with different intensities in the second area A2 and the third area A3. Light having relatively high light extraction efficiency may be emitted in the third area A3 as the strong resonance area, and light which has relatively low light extraction efficiency but is advantageous in securing a viewing angle may be emitted in the second area A2 as the weak resonance area. Accordingly, effects of weak resonance emission and strong resonance emission are combined in each emission area EMA, so that viewing angle characteristics can be improved and light extraction efficiency can be enhanced.

In an embodiment, the second area A2 may surround the first area A1 on a plane, where the second area A2 may be an area in which the scattering layer SCL is not filled but the first electrode layer AE1 and/or the second electrode layer AE2 are disposed. The second area A2 may not overlap with the scattering layer SCL, and may overlap with the first electrode layer AE1 and/or the second electrode layer AE2.

In an embodiment, the third area A3 may surround the second area A2 on a plane, where the third area A3 may be an area in which the scattering layer SCL and/or the second electrode layer AE2 are/is not disposed but the first electrode layer AE1 is disposed. The third area A3 may not overlap with the scattering layer SCL and/or the second electrode layer AE2, and may overlap with the first electrode layer AE1.

In an embodiment, in order to improve the viewing angle characteristics of the display device and prevent deterioration of the front emission efficiency, an area of the first area A1 may be greater than an area of the second area A2. An area of the third area A3 may be greater than the area of the first area A1 and/or the area of the second area A2. In an example, the area of the first area A1 may be about 35% of an area of the emission area EMA, the area of the second area A2 may be about 5% of the area of the emission area EMA, and the area of the third area A3 may be about 60% of the area of the emission area EMA. However, the area ratio of the areas A1 to A3 are not necessarily limited thereto, and may be variously adjusted by considering a target viewing angle characteristic and front emission efficiency.

In an embodiment, the light emitting layer EML may be disposed on the anode electrode AE, the light scattering layer SCL, and/or the pixel defining layer PDL. The light emitting layer EML may be disposed on the anode electrode AE exposed by the pixel defining layer PDL. The light emitting element EML may be disposed on the second electrode AE2 in the first area A1 and/or the second area A2. The light emitting element EML may be disposed directly on the second electrode AE2 in the first area A1 and/or the second area A2. The light emitting layer EML may be disposed directly on the first electrode layer AE1 exposed by the second electrode layer AE2 in the third area A3. The light emitting layer EML may be disposed on the pixel defining layer PDL in the non-emission area NEA. The light emitting layer EML may be disposed directly on the pixel defining layer PDL in the non-emission area NEA.

In an embodiment, the light emitting layer EML may be disposed throughout the sub-pixels SP1 to SP3. In an example, the light emitting element EML may be entirely disposed on the substrate SUB. The light emitting element EML may be partially separated (cut) or bent in boundaries between the sub-pixels SP1 to SP3. However, the invention is not necessarily limited thereto, and portions of the light emitting layer EML, which correspond to the sub-pixels SP1 to SP3, may be separated from each other, and each of the separated portions of the light emitting layer EML may be disposed in the opening of the pixel defining layer PDL.

In an embodiment, the cathode electrode CE may be disposed on the light emitting layer EML and may be disposed throughout all the sub-pixels SP1 to SP3. In an example, the cathode electrode CE may be entirely disposed on the substrate SUB. The cathode electrode CE may be provided as a common electrode, but the invention is not necessarily limited thereto. The cathode electrode CE may serve as a half mirror which allows light emitted from the light emitting layer EML to be partially transmitted therethrough and to be partially reflected therefrom.

In an embodiment, the cathode electrode CE may be a thin metal layer having a thickness to a degree to which light emitted from the light emitting layer EML can be transmitted therethrough. The cathode electrode CE may be formed of a metal material to have a relatively thin thickness or be formed of a transparent conductive material. In an embodiment, the cathode electrode CE may include at least one of various transparent conductive materials including indium tin oxide (ITO), indium zinc oxide (IZO), zinc oxide (ZnOₓ), indium gallium zinc oxide (IGZO), and indium tin zinc oxide (ITZO). In another embodiment, the cathode electrode CE may include at least one of silver (Ag), magnesium (Mg), and mixtures thereof. However, the material of the cathode electrode CE is not limited thereto.

In an embodiment, in each of the sub-pixels SP1 to SP3, holes injected from the anode electrode AE and electrons injected from the cathode electrode CE may be transported into a light emitting layer of the light emitting layer EML to form excitons, and light may be generated when the excitons are changed from an excited state to a ground state. A luminance of the light may be determined according to an amount of current flowing through the light emitting layer EML. A wavelength band of the generated light may be determined according to a configuration of the light emitting layer EML.

In an embodiment, the thin film encapsulation layer TFE may be disposed on the display element layer DPL, where the thin film encapsulation layer TFE may have a single-layer structure or a multi-layer structure. For example, the thin film encapsulation layer TFE may include a first encapsulation layer TFE1, a second encapsulation layer TFE2, and/or a third encapsulation layer TFE3.

In an embodiment, the first encapsulation layer TFE1 may be disposed on the cathode electrode CE and may include at least one of silicon oxide (SiOₓ), silicon nitride (SiNₓ), silicon oxynitride (SiOₓN_{y}), aluminum oxide (AlₓO_{y}), titanium oxide (TiOₓ), tantalum oxide (TaₓO_{y}), hafnium oxide (HfOₓ), and zinc oxide (ZnOₓ).

In an embodiment, the second encapsulation layer TFE2 may be disposed on the first encapsulation layer TFE1 and may include at least one of acrylic resin, epoxy resin, phenolic resin, polyamide resin, polyimide resin, unsaturated polyester resin, poly-phenylene ether resin, poly-phenylene sulfide resin, and benzocyclobutene resin.

In an embodiment, the third encapsulation layer TFE3 may be disposed on the second encapsulation layer TFE2 and may include at least one of silicon oxide (SiOₓ), silicon nitride (SiNₓ), silicon oxynitride (SiOₓN_{y}), aluminum oxide (AlₓO_{y}), titanium oxide (TiOₓ), tantalum oxide (TaₓO_{y}), hafnium oxide (HfOₓ), and zinc oxide (ZnOₓ).

In an embodiment, a sensing layer TS may be disposed on the thin film encapsulation layer TFE and may include a first insulating layer INS1, a first conductive layer MT1, a second insulating layer INS2, a second conductive layer MT2, and/or a third insulating layer INS3.

In an embodiment, the first insulating layer INS1 may be disposed on the thin film encapsulation layer TFE and may be an inorganic insulating layer including an inorganic material. The inorganic insulating layer may include an inorganic insulating material such as silicon oxide (SiOₓ), silicon nitride (SiNₓ), silicon oxynitride (SiOₓN_{y}), aluminum oxide (AlₓO_{y}), titanium oxide (TiOₓ), tantalum oxide (TaₓO_{y}), hafnium oxide (HfOₓ), or zinc oxide (ZnOₓ). In some embodiments, the first insulating layer INS1 may be omitted, or be configured as an uppermost layer of the thin film encapsulation layer TFE.

In an embodiment, the first conductive layer MT1 may be disposed on the first insulating layer INS1 and may be partially opened not to overlap with a light emitting element LD of each sub-pixel SP. In an example, the first conductive layer MT1 may be disposed to overlap with the non-emission area NEA at the periphery of the emission area EMA.

In an embodiment, the first conductive layer MT1 may include a metal layer or a transparent conductive layer. For example, the metal layer may include molybdenum, titanium, copper, aluminum, and alloys thereof. The transparent conductive layer may include one of indium tin oxide (ITO), indium zinc oxide (IZO), zinc oxide (ZnO), indium tin zinc oxide (ITZO), PEDOT, and metal nano wires, but the present disclosure is not necessarily limited thereto. The first conductive layer MT1 may form a connection electrode connecting sensing electrodes to each other.

In an embodiment, the second insulating layer INS2 may be disposed over the first conductive layer MT1 and may include the same material as the first insulating layer INS1, or include at least one material from the materials exemplified as the material constituting the first insulating layer INS1.

In an embodiment, the second conductive layer MT2 may be disposed on the second insulating layer INS2 and may be partially opened not to overlap with the light emitting element LD of each sub-pixel SP. In an example, the second conductive layer MT2 may be disposed to overlap with the non-emission area NEA at the periphery of the emission area EMA.

In an embodiment, the second conductive layer MT2 may include the same material as the first conductive layer MT1, or include at least one material from the materials exemplified as the material constituting the first conductive layer MT1.

In an embodiment, the second conductive layer MT2 may be electrically connected to the first conductive layer MT1 through a contact hole penetrating the second insulating layer INS2.

In an embodiment, the third insulating layer INS3 may be disposed over the second conductive layer MT2, where the third insulating layer INS3 may be an organic insulating layer including an organic material. However, the invention is not necessarily limited thereto. In some embodiments, the third insulating layer INS3 may be formed of an inorganic layer, or have a structure in which an organic layer and an inorganic layer are alternately stacked.

In an embodiment, a light blocking layer LBP may be disposed on the display element layer DPL, the thin film encapsulation layer TFE, and/or the sensing layer TS. The light blocking layer LBP may include an opening overlapping with the light emitting element LD. In an example, the light blocking layer LBP may be disposed to overlap with the non-emission area NEA at the periphery of the emission area EMA.

In an embodiment, the light blocking layer LBP may include a light blocking material so as to prevent light leakage and color mixture. In an example, the light blocking layer LBP may include a black matrix, but the invention is not necessarily limited thereto. In some embodiments, the light blocking layer LBP may include carbon black (CB) and/or titan black (TiBK).

In an embodiment, a color filter layer CFL may be disposed over the light blocking layer LBP and may include color filters CF1 to CF3 each of which accords with a color of each sub-pixel SP. The color filters CF1 to CF3 which respectively accord with the sub-pixels SP1 to SP3 are disposed, so that a full-color image can be displayed.

In an embodiment, the color filter layer CFL may include a first color filter CF1 disposed in the first sub-pixel SP1 to allow light emitted from the first sub-pixel SP1 to be selectively transmitted therethrough, a second color filter CF2 disposed in the second sub-pixel SP2 to allow light emitted from the second sub-pixel SP2 to be selectively transmitted therethrough, and a third color filter CF3 disposed in the third sub-pixel SP3 to allow light emitted from the third sub-pixel SP3 to be selectively transmitted therethrough.

In an embodiment, the first color filter CF1, the second color filter CF2, and the third color filter CF3 may be a red color filter, a green color filter, and a blue color filter, respectively, but the invention is not necessarily limited thereto.

In an embodiment, the first color filter CF1 may include a color filter material which allows light of a first color (or red) to be selectively transmitted therethrough. For example, when the first sub-pixel SP1 is a red sub-pixel, the first color filter CF1 may include a red color filter material.

In an embodiment, the second color filter CF2 may include a color filter material which allows light of a second color (or green) to be selectively transmitted therethrough. For example, when the second sub-pixel SP2 is a green sub-pixel, the second color filter CF2 may include a green color filter material.

In an embodiment, the third color filter CF3 may include a color filter material which allows light of a third color (or blue) to be selectively transmitted therethrough. For example, when the third sub-pixel SP3 is a blue sub-pixel, the third color filter CF3 may include a blue color filter material.

In an embodiment, an overcoat layer OC may be provided on the color filter layer CFL, where the overcoat layer OC may include various materials suitable for protecting lower layers from a foreign matter such as dust or moisture. For example, the overcoat layer OC may include at least one of an inorganic insulating layer and an organic insulating layer. For example, the overcoat layer OC may include epoxy, but invention is not limited thereto.

In accordance with the above-described embodiment, the viewing angle characteristics of the display device can be improved using the scattering layer SCL disposed in the first area A1 of the emission area EMA, and the front emission efficiency can be enhanced through the resonance of the second area A2 and/or the third area A3, in which the scattering layer SCL is not formed.

A method of manufacturing the display device in accordance with the above-described embodiment is described.

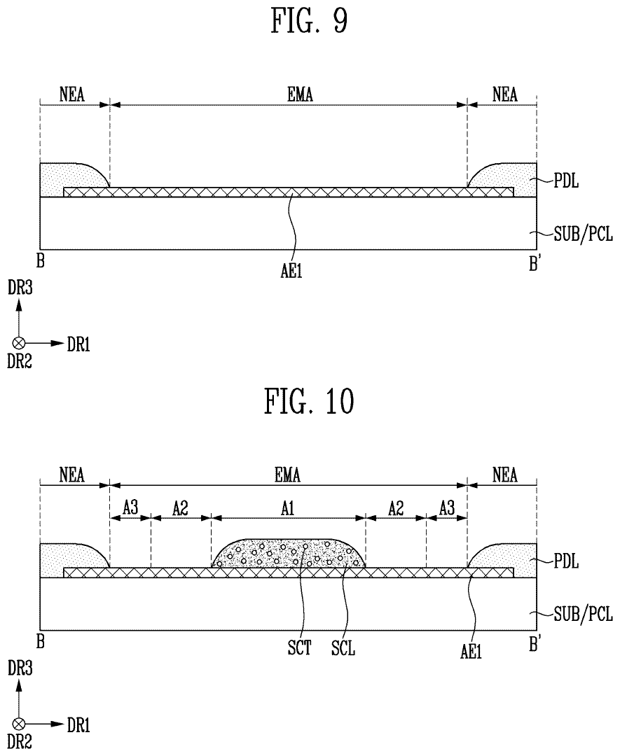

FIGS. 9 to 12 are sectional views illustrating process steps of a method of manufacturing a display device, in accordance with an embodiment. FIGS. 9 to 12 are sectional views illustrating a method of manufacturing the display device shown in FIG. 7, according to an embodiment. For convenience of description, configurations shown in FIGS. 9 to 12 are briefly illustrated, and detailed reference numerals are omitted.

In an embodiment and referring to FIG. 9, a first electrode layer AE1 is formed on a substrate (SUB) (or a pixel circuit layer PCL), and a pixel defining layer PDL is formed on the first electrode layer AE1. The pixel defining layer PDL may include an opening overlapping with an emission area EMA. The opening of the pixel defining layer PDL may expose the first electrode layer AE1 corresponding to the emission area EMA.

In an embodiment and referring to FIG. 10, subsequently, a scattering layer SCL is formed on the first electrode layer AE1, where the scattering layer SCL may be partially formed in a first area A1. The scattering layer SCL may expose the first electrode layer AE1 corresponding to a second area A2 and/or a third area A3.

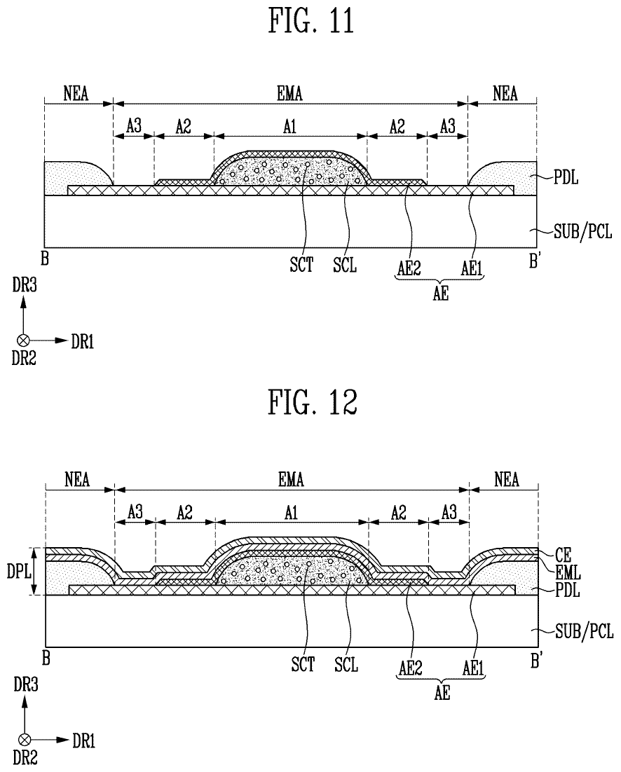

In an embodiment and referring to FIG. 11, subsequently, a second electrode layer AE2 is formed on the scattering layer SCL, where the second electrode layer AE2 may be partially formed in the first area A1 and/or the second area A2. The second electrode layer AE2 may expose the first electrode layer AE1 corresponding to the third area A3.

In an embodiment and referring to FIG. 12, subsequently, a light emitting layer EML is formed on an anode electrode AE and/or the pixel defining layer PDL, and a cathode electrode CE is formed on the light emitting layer EML.

In an embodiment, the light emitting layer EML may be formed on the second electrode layer AE2 in the first area A1 and/or the second area A2. The light emitting layer EML may be formed directly on the second electrode layer AE2 in the first area A1 and/or the second area A2. The light emitting layer EML may be formed on the first electrode AE1 in the third area A3. The light emitting layer EML may be formed directly on the first electrode layer AE1 exposed by the second electrode layer AE2 in the third area A3. The light emitting layer EML may be formed on the pixel defining layer PDL in a non-emission area NEA. The light emitting layer EML may be formed directly on the pixel defining layer PDL in the non-emission area NEA.

In an embodiment, the light emitting layer EML and/or the cathode electrode CE may be formed throughout the sub-pixels SP1 to SP3. In an example, the light emitting layer EML and/or the cathode electrode CE may be entirely formed on the substrate SUB, but the invention is not necessarily limited thereto.

Subsequently, a thin film encapsulation layer TFE and the like may be formed on the cathode electrode CE, thereby completing the display device shown in FIG. 7.

In accordance with the above-described embodiment, the scattering layer SCL is formed in the first area A1 of the emission area EMA, thereby improving the viewing angle characteristics of the display device, and the front emission efficiency can be enhanced through resonance of the second area A2 and/or the third area A3, in which the scattering layer SCL is not formed.

FIGS. 13 to 16 are sectional views illustrating process steps of a method of manufacturing a display device, in accordance with an embodiment. FIGS. 13 to 16 are sectional views illustrating a method of manufacturing the display device shown in FIG. 8, accordance with an embodiment. For convenience of description, configurations shown in FIGS. 13 to 16 are briefly illustrated, and detailed reference numerals are omitted.

In an embodiment and referring to FIG. 13, a first electrode layer AE1 is formed on a substrate SUB (or a pixel circuit layer PCL), and a scattering material layer SML is formed over the first electrode layer AE1. The scattering material layer SML may be entirely formed on the substrate SUB. The scattering material layer SML may include a scatterer SCT.

In an embodiment and referring to FIG. 14, subsequently, a pixel defining layer PDL′ and a scattering layer SCL are formed by etching the scattering material layer SML. The pixel defining layer PDL′ and the scattering layer SCL may be simultaneously formed through the same process. For example, as the scattering material layer SML is removed in a second area A2 and a third area A3, the scattering layer SCL may be formed in a first area A1, and the pixel defining layer PDL′ may be formed in a non-emission area NEA. As such, the pixel defining layer PDL′ and the scattering layer SCL are simultaneously formed, so that the number of masks can be decreased, thereby simplifying processes and reducing cost.

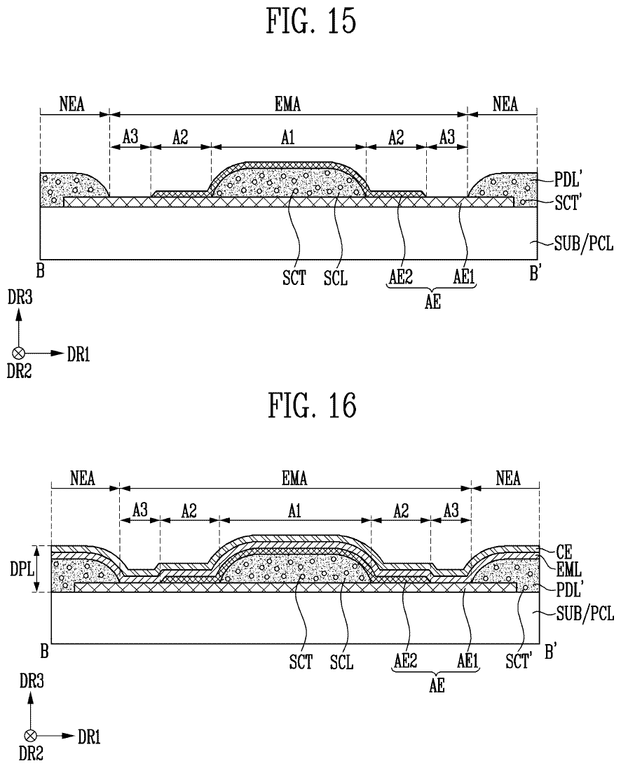

In an embodiment and referring to FIG. 15, subsequently, a second electrode layer AE2 is formed on the scattering layer SCL, where the second electrode layer AE2 may be partially formed in the first area A1 and/or the second area A2. The second electrode layer AE2 may expose the first electrode layer AE1 corresponding to the third area A3.

In an embodiment and referring to FIG. 16, subsequently, a light emitting layer EML is formed on an anode electrode AE and/or the pixel defining layer PDL′, and a cathode electrode CE is formed on the light emitting layer EML.

In an embodiment, the light emitting layer EML may be formed on the second electrode layer AE2 in the first area A1 and/or the second area A2. The light emitting layer EML may be formed directly on the second electrode layer AE2 in the first area A1 and/or the second area A2. The light emitting layer EML may be formed on the first electrode AE1 in the third area A3. The light emitting layer EML may be formed directly on the first electrode layer AE1 exposed by the second electrode layer AE2 in the third area A3. The light emitting layer EML may be formed on the pixel defining layer PDL′ in the non-emission area NEA. The light emitting layer EML may be formed directly on the pixel defining layer PDL′ in the non-emission area NEA.

In an embodiment, the light emitting layer EML and/or the cathode electrode CE may be formed throughout the sub-pixels SP1 to SP3. In an example, the light emitting layer EML and/or the cathode electrode CE may be entirely formed on the substrate SUB, but the invention is not necessarily limited thereto.

In an embodiment, subsequently, a thin film encapsulation layer TFE and the like may be formed on the cathode electrode CE, thereby completing the display device shown in FIG. 8.

In accordance with the above-described embodiment, the scattering layer SCL is formed in the first area A1 of the emission area EMA, thereby improving the viewing angle characteristics of the display device, and the front emission efficiency can be enhanced through resonance of the second area A2 and/or the third area A3, in which the scattering layer SCL is not formed, which has been described above. In addition, the pixel defining layer PDL′ and the scattering layer SCL are simultaneously formed, so that the number of masks can be decreased, thereby simplifying processes and reducing cost.

In accordance with an embodiment, a scattering layer is formed in an emission area, thereby improving the viewing angle characteristics of the display device, and the front emission efficiency can be enhanced using a resonance area in which the scattering layer is not formed.

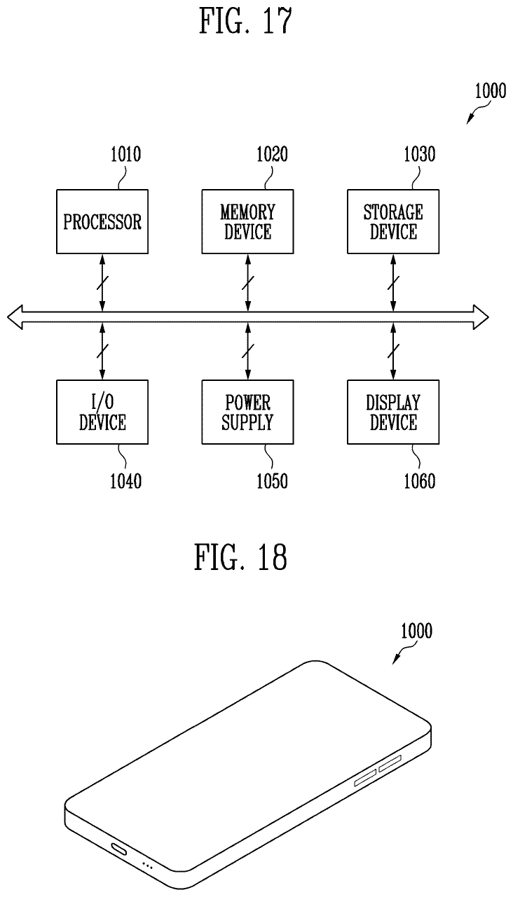

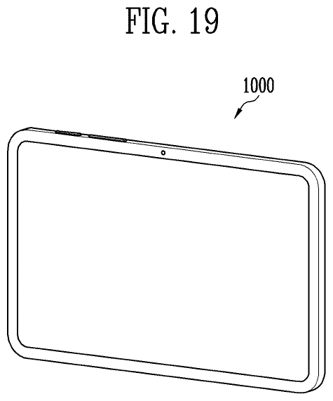

FIG. 17 is a block diagram illustrating an electronic device 1000 including a display device, in accordance with an embodiment. FIG. 18 is a graphical image illustrating an embodiment where the electronic device 1000 of FIG. 17 is a smartphone. FIG. 19 is a graphical image illustrating an embodiment where the electronic device 1000 of FIG. 17 is a tablet computer.

In an embodiment and referring to FIGS. 17 to 19, the electronic device 1000 may include a processor 1010, a memory device 1020, a storage device 1030, an input/output (I/O) device 1040, a power supply 1050, and a display device 1060. The display device 1060 may be the display device or display panel of FIG. 1. The electronic device 1000 may further include various ports for communication with a video card, a sound card, a memory card, a USB device, or other systems. In an embodiment, as illustrated in FIG. 18, the electronic device 1000 may be a smartphone. In an embodiment, as illustrated in FIG. 19, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

In an embodiment, the processor 1010 may perform specific calculations or tasks. In an embodiment, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

In an embodiment, the memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

In an embodiment, the storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

In an embodiment, the I/O device 1040 may include input devices such as a keyboard, a keypad, a touchpad, a touch screen, and a mouse, and output devices such as a speaker and a printer. In an embodiment, the display device 1060 may be integrated with the I/O device 1040.

In an embodiment, the power supply 1050 may supply power needed to perform the operation of the electronic device 1000. For example, the power supply 1050 may include a power management integrated circuit (PMIC). In an embodiment, the power supply 1050 may supply power to the display device 1060.

In an embodiment, the display device 1060 may display images in response to image data signals and/or control signals from the processor 1010. The display device 1060 may be connected to other components through the buses or other communication links.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments. Accordingly, it will be understood by those of skill in the art that various changes in form and details may be made without departing from the spirit and scope of the invention.

What is claimed is:

1. A display device comprising:
a pixel defining layer surrounding an emission area;
a first electrode including a first electrode layer and a second electrode layer;
a scattering layer disposed between the first electrode layer and the second electrode layer;
a light emitting layer disposed on the pixel defining layer and the first electrode; and
a second electrode disposed on the light emitting layer,
wherein a width of the scattering layer is smaller than a width of the emission area.

2. The display device of claim 1, wherein the second electrode layer is disposed between the first electrode layer and the light emitting layer.

3. The display device of claim 1, wherein the emission area includes:
a first area overlapping with the scattering layer; and
a second area not overlapping with the scattering layer, wherein the second area overlaps with the second electrode layer.

4. The display device of claim 3, wherein the second area surrounds the first area on a plane.

5. The display device of claim 3, wherein an area of the first area is greater than an area of the second area.

6. The display device of claim 3, wherein the emission area further includes a third area not overlapping with the second electrode layer, wherein the third area overlaps with the first electrode layer.

7. The display device of claim 6, wherein the third area surrounds the second area on a plane.

8. The display device of claim 6, wherein an area of the third area is greater than the area of the first area.

9. The display device of claim 6, wherein an area of the third area is greater than the area of the second area.

10. The display device of claim 1, wherein a width of the second electrode layer is greater than the width of the scattering layer and smaller than the width of the emission area.

11. The display device of claim 1, wherein the width of the emission area is greater than a width of the second electrode layer and smaller than a width of the first electrode layer.

12. The display device of claim 1, wherein the pixel defining layer includes a scatterer.

13. The display device of claim 1, wherein the pixel defining layer includes at least one penetration hole.

14. A display device comprising:
a pixel defining layer including an opening exposing a first electrode layer;
a scattering layer disposed in a same layer as the pixel defining layer, wherein the scattering layer is spaced apart from the pixel defining layer on a plane;
a second electrode layer disposed on the scattering layer;
a light emitting layer disposed on the second electrode layer; and
a second electrode disposed on the light emitting layer.

15. The display device of claim 14, wherein the pixel defining layer and the scattering layer are disposed directly on the first electrode layer.

16. The display device of claim 14, wherein the pixel defining layer includes a scatterer.

17. The display device of claim 14, wherein the pixel defining layer surrounds the scattering layer on a plane.

18. The display device of claim 14, wherein, on a plane, the pixel defining layer surrounds the second electrode and is spaced apart from the second electrode.

19. The display device of claim 14, wherein a width of the second electrode layer is greater than a width of the scattering layer and smaller than a width of the opening.

20. An electronic device comprising:
a processor providing input image data; and
a display device displaying an image based on the input image data, the display device including sub-pixel areas,
wherein the display device comprises:
a pixel defining layer surrounding an emission area;
a first electrode including a first electrode layer and a second electrode layer;
a scattering layer disposed between the first electrode layer and the second electrode layer;
a light emitting layer disposed on the pixel defining layer and the first electrode; and
a second electrode disposed on the light emitting layer,
wherein a width of the scattering layer is smaller than a width of the emission area.
